(19) United States
(12) Patent Application Publication
(10) Pub. No.: US 2009/0029292 A1
(43) Pub. Date: Jan. 29, 2009

(54) ENGRAVING WITH AMPLIFIER HAVING MULTIPLE EXIT PORTS

(76) Inventor: Haim Chayet, Nes Ziona (IL)

Correspondence Address: David A. Novais;Patent Legal Staff, Eastman Kodak Company, 343 State Street, Rochester, NY, 14650-2201, US

(21) Appl. No.: 11/781,388

(22) Filed: Jul. 23, 2007

(51) Int. Cl. G03F 7/00

(52) U.S. Cl. 430/306; 430/256; 430/945

(57) ABSTRACT

An apparatus for direct engraving comprises: a plurality of laser diode emitting at different wavelengths; a multiplexer (11) for collecting the plurality of laser sources into a single laser beam; a rare earth doped fiber amplifier (12) to amplify the single laser beam to form an amplified single laser beam; a demultiplexer to split the single laser beam into a plurality of amplified laser sources; and an imaging means to apply the plurality of amplified laser sources for imaging a printing plate (55).

### FIELD OF THE INVENTION

The invention relates to doped fiber amplification (DFA) of a plurality of laser sources composed of different wavelength laser diodes to produce printing blocks more efficiently.

### BACKGROUND OF THE INVENTION

In current printing technology the final image is conveyed to the substrate by transferring ink from a printing block to the imaged surface. The printing block comprises light sensitive material wherein the image is formed by light exposure of selective areas with laser source. The light exposure can be made through a patterned mask (film), however, most often this is achieved by directly controlling the exposing light beam commonly in a process referred to as computer to plate (CtP); in a CtP system a laser beam is scanned over the surface (plate), and the intensity of the laser is modulated according to the data generated by a computer.

One family of plates used in direct laser imaging is known as flexographic (flexo) printing plates made of a flexible material, such as polymer or rubber, so that it can be attached to a roller or cylinder for ink application. Ink transfer occurs when raised images on the plate come into contact with the substrate during the printing process. For direct laser image setting, the flexo plate consist of upper level light sensitive material that acts as photo resist mask for a lower layer photopolymer material. In a first step, the upper level is imaged (ablated) to a desired pattern. In a subsequent step the flexo plate is exposed with ultraviolet (UV) light. The photopolymer cures material beneath the non removed areas of the mask, while under the removed areas the photopolymer stays in its uncured form and washes out in subsequent developing step. For mechanical support these two layers rest on a third substrate layer made of flexible polymer.

An alternative method for producing high resolution flexo plates where the UV exposure and subsequent developing steps are eliminated, is by direct engraving into the polymer. Imaging of the plate is achieved by selective removal of the material by laser ablation. The laser is applied one or more times on the surface of the plate until a 3D feature with required depth is formed. The depth of ablation depends on material properties such as ability of the material to absorb laser energy, the absorption depth, and other properties of the material. For a given material, there is a minimum required energy density for the laser beam for the ablation to occur, above this threshold the productivity of the plate setters will depend on the power of the laser.

This requirement of high power from a laser source is often contradictory to the requirement of high resolution imaging. For the laser to provide an adequate imaging resolution the laser spot must have the ability to be focused to a particular spot size. However, due to diffraction effects there is a fundamental minimum to the size the laser spot can be focused, which depends on the wavelength of the laser source and the angular divergence of the laser beam.

A laser spot focused to a particular spot size with minimum angular divergence set by the theoretical limit is said to be diffraction limited. A quantitative measure to how much the laser beam exceeds this theoretical limit is provided by the so called the M² model. Characterization of laser beams by “M² model” is discussed by (Thomas Johnston and Michael Sanset in “Handbook of Optical and Laser Scanning”, Ed. G. F. Marshal). Essentially, a spot produced by laser source and ideal lens used to focus the laser beam is given by the following formula:

$$Spot size = \frac{4 {M}^{2} λ}{π} \frac{f}{D}$$

Where λ is wavelength of the laser source, f is the focal length of the imaging lens, and D is the input beam diameter at the lens. M² can be thought as the number of times the beam divergence exceeds the diffraction limit. For diffraction limited beam M²=1. CO₂ laser which emit light at wavelength, λ=10.6 λm is an example of popular laser system that is limited because of a long wavelength. On the other hand, high power laser diodes are usually designed to emit at wavelength below 1 λm, but powerful emission can only be realized with multimode laser cavity with considerable divergence, that is, M² many times larger than unity.

For these reasons, and with the advent of fiber lasers technology, fiber lasers, based on ytterbium (Yb) doped glass fiber, emerge as a technology of choice for high power laser application, providing high beam quality: M² close to unity, and wavelength of the order λ≈1.1 μm. Fiber lasers capable of emitting many hundreds of watts are commercially available from various companies, such as for example IPG Photonics. A review on fiber lasers is given by “Rare Earth Doped Fiber Lasers and Amplifiers”, Second Edition, Ed. Michel J. F. Digonnet.

While a single fiber laser is capable of providing ample output power, there is a practical limitation to the power of a single laser beam that can be useful in a CtP system. Conventionally, in a CtP, the plate is clamped to a rotating drum and the laser beam is scanned over the plate in an axis parallel to axis of rotation. The productivity can be expressed as the total area of plate material processed per unit time. Therefore to take advantage of increased power form a laser source to increase productivity of the platesetter, the drum needs to be rotated fast. Similarly, if a linear scanning method is used, known as “flatbed or “capstan”, the plate is scanned relative to the laser beam linearly the linear velocity needs to be increased accordingly.

Usually however, there are mechanical constrains which makes higher scanning speeds increasingly complicated. Therefore, the common approach for increased productivity is to use a plurality of fiber laser beams, positioned into a contiguous array, each beam is modulated independently for simultaneous imaging of the plate. Such approach is commonly used with plurality of laser diodes sources, wherein each diode is modulated by direct modulation of the driving current. However, the laser diode fiber laser is limited to direct current modulation to moderate frequency range, usually less than 100 KHz which is less than required for high speed imaging.

To overcome this shortcoming of fiber laser, the standard approach was to use acousto optic modulator (AOM) to modulate the beam. For plurality of beams, a number of AOMs are utilized, and each beam was provided with a separate AOM. As an alternative, acousto optic deflector (AOD), driven by multiple RF voltage frequencies, was provided with each RF frequency amplitude modulated corresponding for a particular beam channel. U.S. Pat. No. 6,822,669 (Fischer et al.) describes such arrangement of plurality of fiber lasers in conjugation with number of AOM, or single AOM driven by several RF voltages.

While AOM can provide the means for high rate of modulation, there are significant disadvantages associated with it, in addition to increased complexity of adding additional components and costs to the imaging head. Since the AOM is not perfectly transparent the light transmitted through the modulator is attenuated.

Another disadvantage associated with AOM is related to its reliability. When light beam is amplitude modulated by the AOM, the rise time of the modulation is proportional to the beam diameter passing through the modulator. If the AOM is operated at high modulation rates the laser beam diameter incident on the AOM must be small, and therefore the standard approach has been to focus the beam at the input aperture of the modulator. This results in significant increase in the optical power density of the beam and can lead to damage of the AOM. Even slight excess of power density can damage the crystal inside AOM, leading to optical absorption of higher portions of the laser beam and inevitable failure of the device. Yet, another disadvantage of AOM is associated with the RF voltage driver. As the electric to acoustic energy conversion is not efficient, the heat produced by the dissipated electrical energy within the RF driver needs to be removed from the system, often by water cooling, which adds to complexity and impairs the reliability of the CtP. It is the objective of this invention to provide a method for constructing a plurality of laser beams for CtP utilizing fiber laser technology which circumvents the use of acousto optics devices.

In a fiber laser the gain medium for laser action is a fiber doped with ions such as ytterbium (Yb³⁺), erbium (Er³⁺), neodymium (Nd³⁺), or other rare-earth metals, that is pumped with one or more laser diode. For laser action to take place a cavity is formed by introducing a type of resonant reflector into the fiber, which can be a mirror, a fiber ring, fiber optic couplers, or other arrangements described in the literature. If no resonant reflectors are introduced into the gain medium, the doped and pumped fiber can serve as a light amplifier to low power laser light which is launched into it. The arrangement is then generally referred to as ‘doped fiber amplifier’ (DFA). The action of DFA gain medium is not limited to amplification of a single low power laser light. Several laser inputs can be amplified simultaneously by the same DFA provided that the launched wavelengths of laser light lies within the optical spectral bandwidth of the DFA. Furthermore, the DFA can be cascaded in several stages to provide several stages of amplification.

DFA applications are extensively used in optical fiber communication, particularly in wavelength-division multiplexing (WDM) where predominantly erbium (Er³⁺) doped fiber amplifiers (EDFA) are used to amplify optical signals within several channels, each channel of different wavelength that propagate in optical fibers.

U.S. Pat. No. 6,212,310 (Waarts et al.) describes coupling a plurality of laser sources into a single fiber waveguide. The signal amplification in the single waveguide is achieved via doped fiber amplification means.

EP Patent No. 0846562 (Tamaki) describes an image recording apparatus and method, utilizing doped fiber amplification means. The DFA is used in conjunction with amplification of a single laser source, the amplified laser source is then applied for purposes of engraving a printing block.

### SUMMARY OF THE INVENTION

Briefly, according to one aspect of the present invention an apparatus for direct engraving comprises: a plurality of laser diode emitting at different wavelengths; a multiplexer for collecting the plurality of laser sources into a single laser beam; a rare earth doped fiber amplifier to amplify the single laser beam to form an amplified single laser beam; a demultiplexer to split the single laser beam into a plurality of amplified laser sources; and an imaging means to apply the plurality of amplified laser sources for imaging a printing plate.

### BRIEF DESCRIPTION OF THE DRAWINGS

FIG. 1 is a schematic showing combining of laser beams from multiple laser sources having different wavelengths, their amplification via a single doped fiber amplifier, and then splitting the beam into its wavelength components and exposing them on a printing plate.

FIG. 2A is a schematic of a multiplexer based on diffraction grating.

FIG. 2B is a schematic of a multiplexer based on prism.

FIG. 3A shows wide spectral width and low separation of the plurality of the laser sources.

FIG. 3B shows wide spectral width with increased separation of the plurality of the laser sources.

FIG. 3C shows narrow spectral width with broad separation of the plurality of the laser sources.

FIG. 4A shows a graph of erbium gain vs. laser beam wavelength.

FIG. 4B shows a graph of ytterbium gain vs. laser beam wavelength.

FIG. 5 shows an ytterbium based DFA example for CTP implementation.

FIG. 6 shows cascading of two DFAs in a row to achieve stronger amplification.

### DETAILED DESCRIPTION OF THE INVENTION

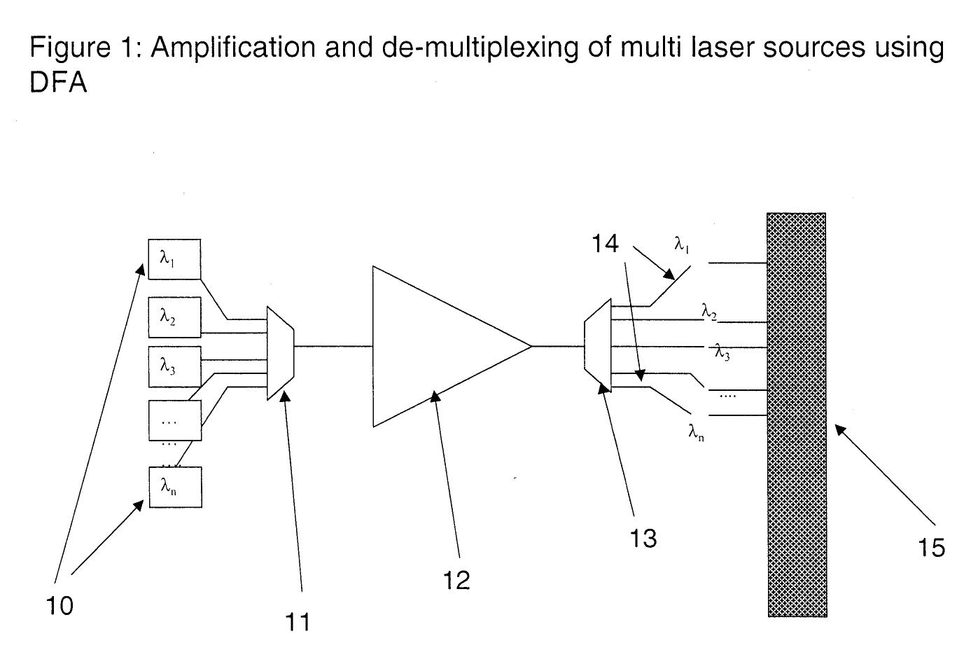

A method for producing a printing block with a multiple laser sources composed from different wavelength laser diodes 10, as is depicted in FIG. 1. The light output from laser diodes light is coupled to a rare earth doped fiber amplifier (DFA) 12. The output from the amplification stage is then split into different demultiplexed laser beams 14, according to the light wavelengths, by means of an optical demultiplexer 13. The demultiplexed laser beams 14 are then exposed on the printing plate 15. The action of optical demultiplexer is to receive from the fiber a beam composed of multiple optical wavelengths, and separate them into wavelength components into the different ports. Similarly, the device can perform in reverse for wavelength multiplexing: different wavelengths that introduced to its multiple ports combine into a multi-wavelength beam. Such an arrangement is shown in FIG. 1 where optical multiplexer 11 couples the light from laser sources 10 into the DFA 12. Light can be launched into DFA by simple fiber coupler; however, this results in significant optical power loss which is proportional to the number of channels used.

With reference made to FIG. 1, after the light beam of each individual laser source is amplified by the DFA, its exit port is decided by its wavelength, using a an optical demultiplexer 13.

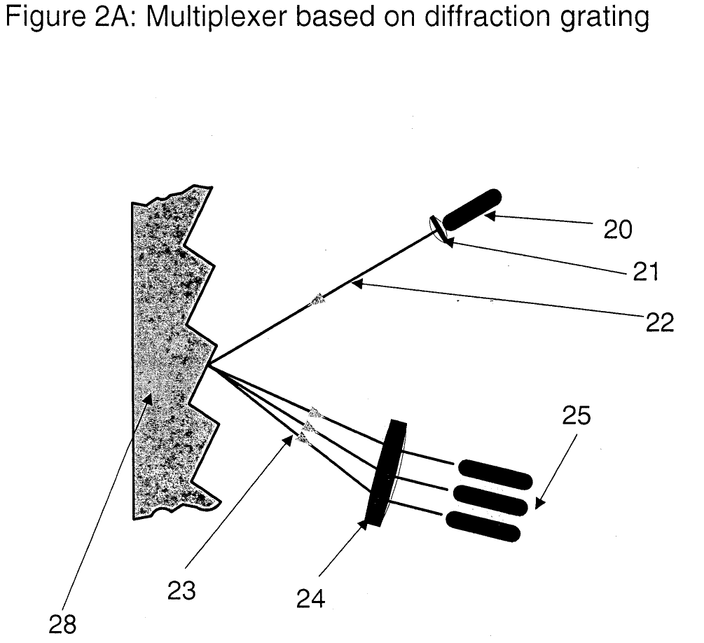

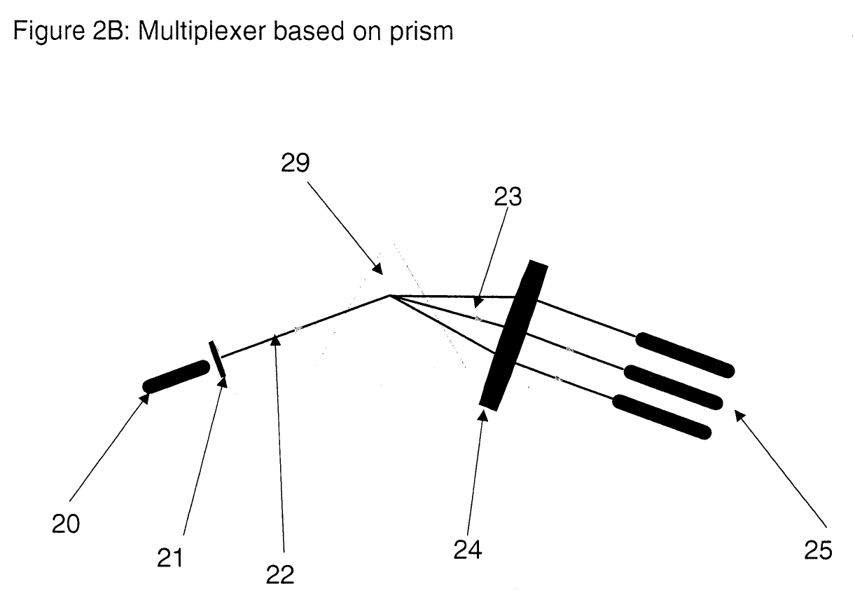

Most commonly optical multiplexers are based on dispersive components, such as diffraction gratings or prisms, but can be realized on principles of interferometery. FIGS. 2A and 2B illustrate two different implementations of such a demultiplexer. FIG. 2A demonstrates de multiplexing which is based on diffraction grating device 28, whereas FIG. 2B is based on a prism 29.

In FIG. 2A the light beam 22 from laser light source 20 passes through a lens 21, and is incident on the dispersive grating device 28. The resulting demultiplexed plurality of laser beams 23 of different wavelength components are coupled by lens 24 into different waveguides 25.

In FIG. 2B a prism 29 acts a dispersive component and splits the light beam 23 into wavelength components which are then coupled into the different ports.

It is understood that the path of the light beam can be retraced as propagating in reverse direction, then the device operates as a multiplexer, combining the light of different ports 25 into a single port 23. Optical multiplexer are discussed in “Fundamentals of Optical Waveguides” by Katsunari Okamoto, Academic Press Inc.

The laser sources 10, at different wavelength are fiber coupled semiconductor diode lasers. Since the beams of laser diodes are amplified by the DFA, and because optical amplification occurs in a finite range of optical frequencies called the gain bandwidth, the wavelength of the laser sources must be positioned within the operational wavelength range of the DFA. For doping with erbium ions the useful range for amplification is 1535 nm to 1565 nm and can be extended to 1610 nm. When doping is with ytterbium ions the applicable wavelength is 1030 to 1100 nm.

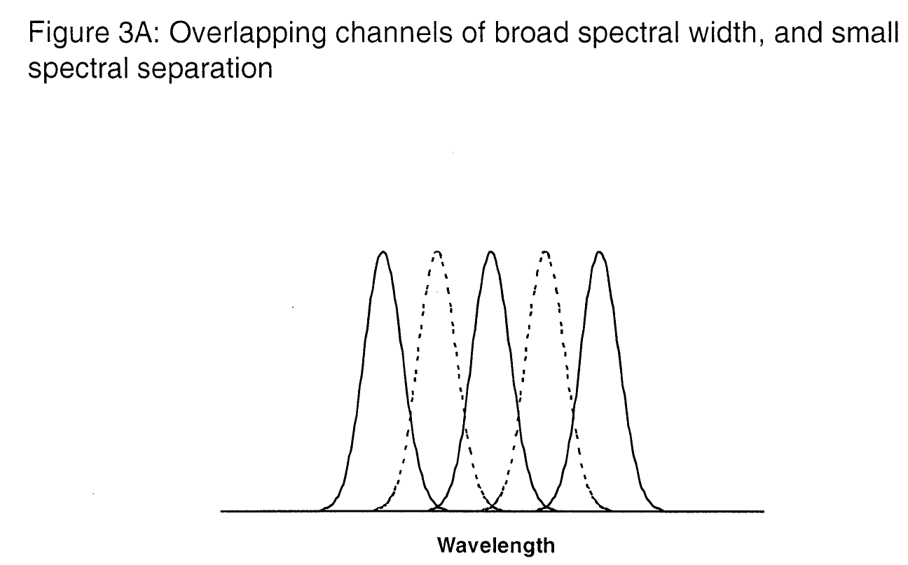

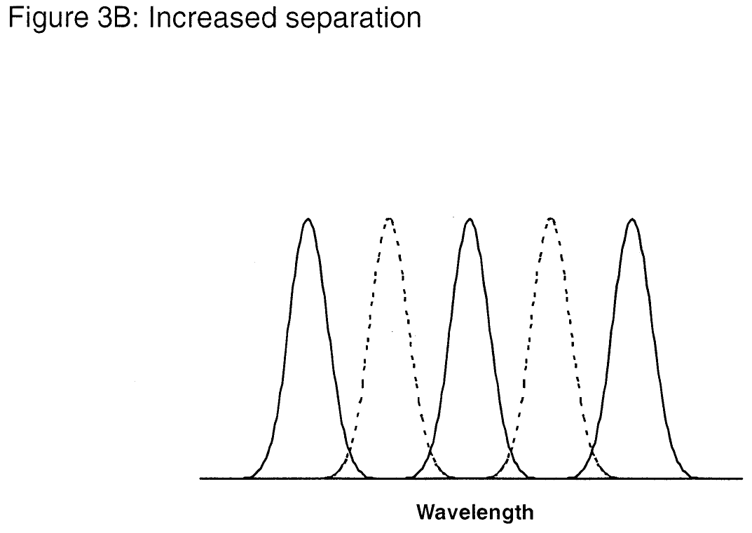

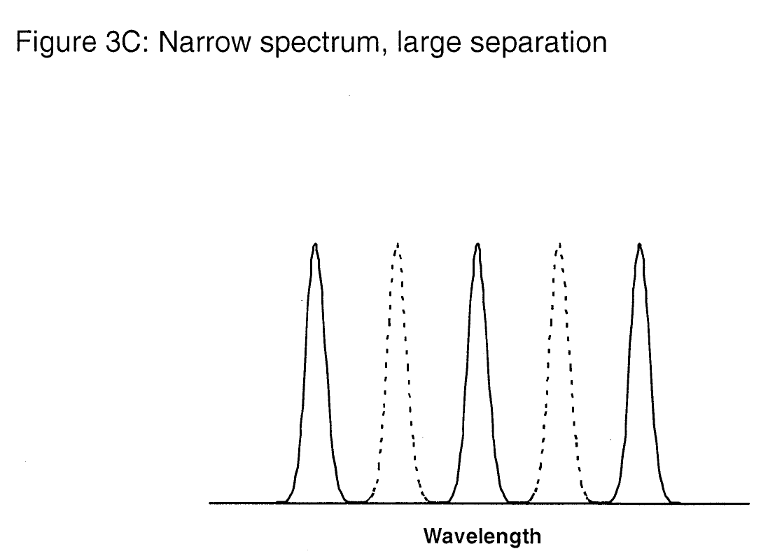

It is important that spectral overlapping is to be avoided between the input laser sources; width for the individual laser sources needs to be narrower than the wavelength separation between individual sources. This is described in FIGS. 3A, 3B and 3C. FIG. 3A shows the spectral width of the individual laser sources is wide and the separation between the channels is small, therefore laser channels have significant overlapping. In FIG. 3B the spectral width of the laser sources is wide but the separation now is increased, the overlapping is seen to decrease. With narrow spectrum and broad separation as is shown FIG. 3C the channels have negligible overlap and therefore will be routed to the exit port without cross talk of different channels.

Since it is desirable to operate with high beam quality, i.e., M² close to unity, the preferred DFA is a single mode fiber. The laser sources therefore are preferably single mode laser with single mode fiber output. Because the laser diodes are amplified high power is not required and therefore single mode operation does not introduce a constraint on output power requirement. Furthermore the great advantage of laser diodes is the ability of internal intensity modulation, by modulating the drive current of the laser diode. Single mode laser diodes are better suited for internal modulation at high rates. Single mode laser diodes at wavelength suitable for ytterbium DFA, or erbium DFA are available, for examples available by Lumics—GmbH http://www.lumics.com/.

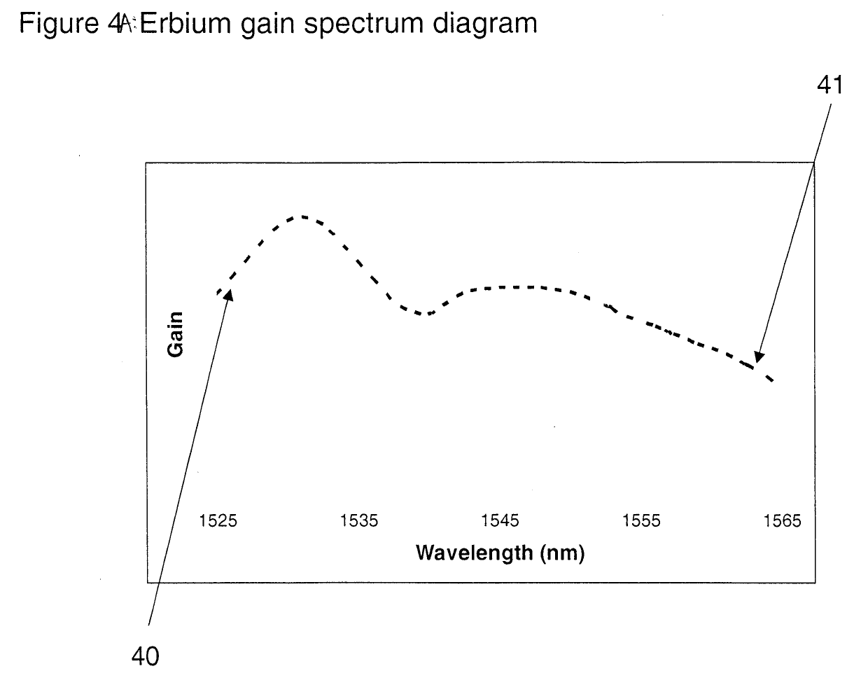

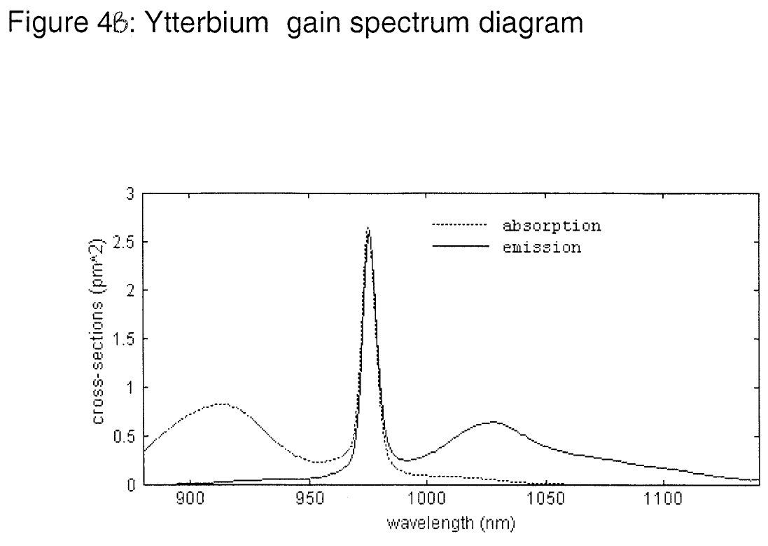

The wavelength division de-multiplexer channels are chosen according to the wavelength of the laser sources, and the number of ports determined by the number of laser sources. The DFA, can be ytterbium doped fiber amplifier (YDFA), which is suitable for amplification in the wavelength range of 1050-1100 nm as shown in FIG. 4B. The absorption spectrum (dotted line) represents the efficiency at which the doped fiber absorbs photonic energy. Because the peak occurs near 970 nm the diode lasers used for pumping the DFA are designed around this wavelength. The emission curve represent the relative power of emitted radiation of excited DFA. When 970 nm peak is used for pumping the DFA the portion of the curve from 1050 nm 1100 nm is used for amplification. Such YDFA are available for example from IPG Photonics, YAR-LP-SF series (http://www.ipgphotonics.com/index.htm).

As can be inferred from their curve in FIG. 4A, Erbium doped fiber amplifiers (EDFA) are suitable for operation at longer wavelength range of 1535 to 1565 nm, and can be extended to 1610 nm. Such amplifiers are also readily available example by IPG Photonics, as for example EAD and EAR series http://www.ipgphotonics.com/index.htm

It is evident from FIGS. 4A and 4B that the gain spectrum of the DFA is not flat. For example in FIG. 4A for erbium DFA the gain at wavelength 1525 nm 40 differs significantly from that at wavelength 1565 nm 41. Various schemes are known in art for gain equalization of different channels, intensity modulation, controlling the intensity of the laser diodes beams at the input of the DFA is one of them.

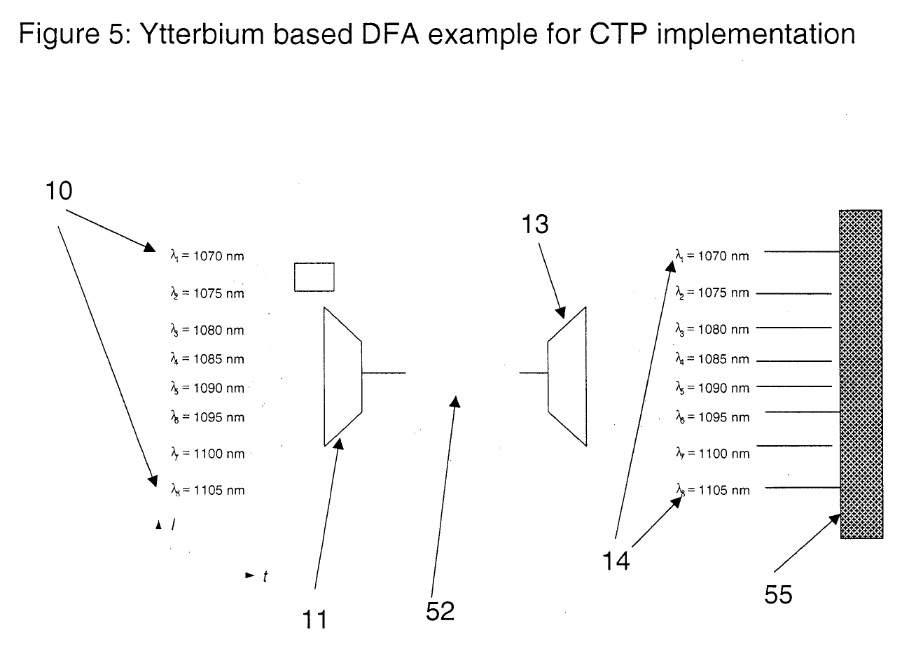

In preferred arrangement the proposed method of the imaged plate is insensitive to wavelength over the useful range of the fiber amplifier used, and the spectral bandwidth used. As an example, if ytterbium ion based DFA is used, the useful spectral range for amplification 1030 to 1100 nm. In a possible arrangement the CtP consists of 8 beams with wavelength spacing of 5 nm between channels with the first channel centered at 1070 nm. Since the spacing is 5 nm, the second at 1075 nm, and so on, the last eighth channel 8^{th} at 1105 nm. This is described in FIG. 5. Laser sources 10 enters into optical multiplexer 11, then into ytterbium based doped amplifier 52 to be demultiplexed by optical demultiplexer 13 and expose printing plate 55. Printing plate 55 should carry the features of equal sensitivity at the range from 1070 nm to 1105 nm.

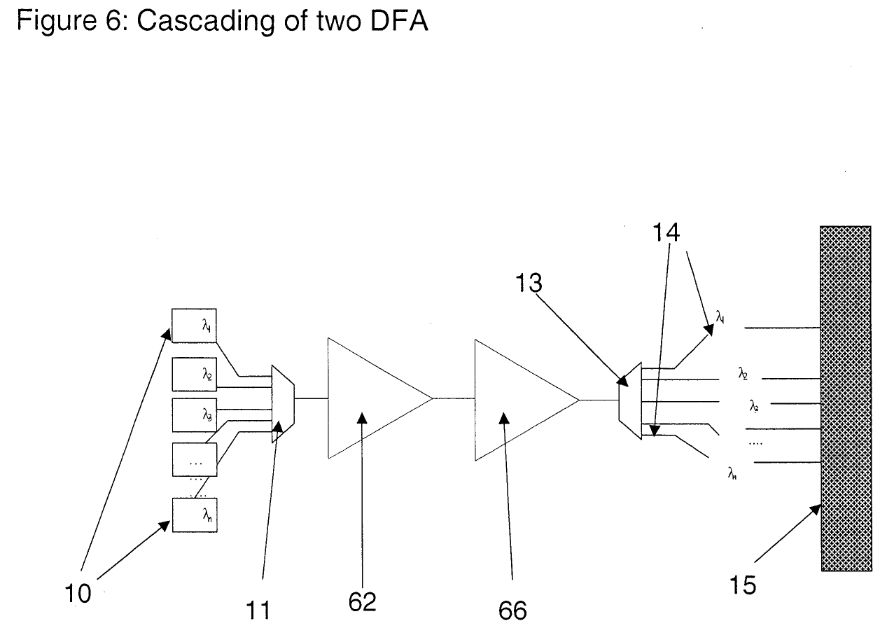

The method of this invention offers the advantage of deploying a modular approach, allowing of cascading several amplifier stages, amplifying the output power to the required level. FIG. 6 shows a method at which the amplification is performed by deploying two rare earth based amplifiers, configured in a cascaded. Laser beams enters into first stage rare earth amplifier 62, and then propagates into second stage rare earth amplifier 66, before it enters into the demultiplexer 13. In this respect, the output coupling of light out amplifier is inherently better than that of a laser, since no feedback light is required. Imaging with plurality of powerful laser beams is made possible without increasing the number of powerful laser sources, and hence the number of associated acousto optic modulation means.

Another benefit of using a amplification stage rather than discrete powerful laser is that it is much simpler to control the modulation of lower power of individual laser diodes than that of a powerful laser source, moreover, since internal current modulation of laser diodes is straightforward.

The invention has been described in detail with particular reference to certain preferred embodiments thereof, but it will be understood that variations and modifications can be effected within the scope of the invention.

### Parts List

10 different wavelength laser diode sources
11 optical multiplexer
12 earth doped fiber amplifier (DFA)
13 optical demultiplexer
14 demultiplexed laser beams
15 printing plate
20 light source
21 lens
22 light beam
23 demultiplexed plurality of laser beams
24 lens
25 waveguides
28 grating device
29 prism
40 1525 nm gain spectrum
41 1565 nm gain spectrum
52 ytterbium doped fiber amplifier
55 printing plate
62 first stage rare earth amplifier
66 second stage rare earth amplifier

1. An apparatus for direct engraving comprising:
a plurality of laser diode emitting at different wavelengths;
a multiplexer for collecting said plurality of laser sources into a single laser beam;
a rare earth doped fiber amplifier to amplify said single laser beam to form an amplified single laser beam;
a demultiplexer to split said single laser beam into a plurality of amplified laser sources; and
an imaging means to apply said plurality of amplified laser sources for imaging a printing plate.

2. The apparatus of claim 1, wherein the rare earth doped fiber amplifier is formed of at least two, single rare earth doped fiber amplifier cascaded in the direction of the optical propagation path.

3. The apparatus of claim 1, wherein the rare earth doped fiber amplifier is ytterbium based.

4. The apparatus of claim 1, wherein the rare earth doped fiber amplifier is erbium based.

5. The apparatus of claim 1, wherein the rare earth doped fiber amplifier is neodymium based.

6. The apparatus of claim 1, wherein the demultiplexer is based on a diffraction grating device.

7. The apparatus of claim 1, wherein the demultiplexer is based on a prism.

8. A method for direct engraving comprising the steps of:
providing a plurality of laser beams at different wavelengths;
multiplexing said laser beams into a single laser beam;
amplifying said single laser beam using rare earth doped fiber amplifier to form an amplified single laser beam;
splitting said amplified single laser beam into a plurality of amplified laser sources; and
imaging said plurality of amplified laser source on a printing plate.

9. The method of claim 8, wherein the rare earth doped fiber amplifier is formed of more than one rare earth doped fiber amplifier cascaded in the direction of the optical propagation path.

10. The method of claim 8, wherein the rare earth doped fiber amplifier is ytterbium based.

11. The method of claim 8, wherein the rare earth doped fiber amplifier is erbium based.

12. The method of claim 8, wherein the rare earth doped fiber amplifier is neodymium based.

13. The method of claim 8, wherein the demultiplexer is a diffraction grating device.

14. The method of claim 8, wherein the demultiplexer is a prism.

15. A method for direct engraving comprising the steps of:
providing a plurality of laser beams;
multiplexing said laser beams into a single laser beam;
amplifying said single laser beam using an amplifier to form an amplified single laser beam;
splitting said amplified single laser beam into a plurality of amplified laser sources; and
imaging said plurality of amplified laser source on a substrate.

16. The method of claim 15, wherein said amplifier is rare earth doped fiber amplifier.
